(19) United States
(12) Patent Application Publication
(10) Pub. No.: US 2011/0306198 A1
(43) Pub. Date: Dec. 15, 2011

(54) METHOD OF FABRICATING SEMICONDUCTOR INTEGRATED CIRCUIT DEVICE

(75) Inventors: Yong-Kuk Jeong, Suwon-si (KR); Dong-Suk Shin, Yongin-si (KR); Jong-Hun Kim, Seoul (KR); Hyun-Kwan Yu, Suwon-si (KR); Ki-eun Kim, Seoul (KR)

(73) Assignee: SAMSUNG ELECTRONICS CO., LTD., Suwon-si (KR)

(21) Appl. No.: 13/157,615

(22) Filed: Jun. 10, 2011

(30) Foreign Application Priority Data
Jun. 11, 2010 (KR) 10-2010-0055691

(51) Int. Cl. H01L 21/28

(52) U.S. Cl. 438/595; 257/E21.19

(57) ABSTRACT

A method of fabricating a semiconductor integrated circuit device includes forming a gate pattern on a semiconductor substrate, the gate pattern having a gate insulation film and a gate electrode. A spacer is formed on sidewalls of the gate pattern. A silicide layer is formed by a silicide process on at least one portion of the semiconductor substrate exposed by the gate pattern and the spacer, the silicide layer being formed using a silicide process. A stress buffer layer is formed on a resultant structure having the silicide layer. A stress film is formed on the stress buffer layer.

### CROSS-REFERENCE TO RELATED APPLICATION

This application claims priority under 35 U.S.C. 119 to Korean Patent Application No. 10-2010-0055691, filed in the Korean Intellectual Property Office on Jun. 11, 2010, the entire contents of which are herein incorporated by reference.

### BACKGROUND

1. Field of the Inventive Concept

The present inventive concept relates to a method of fabricating a semiconductor integrated circuit device, and more particularly, to a method of fabricating a semiconductor integrated circuit device having improved reliability.

2. Description of the Related Art

In general, a MOS field effect transistor (MOSFET) is constructed such that a gate electrode formed on a semiconductor substrate is insulated by a gate insulation film and source/drain areas are formed at both sides of the gate electrode. In the MOSFET, when an appropriate bias voltage is applied to the MOSFET, a channel area is formed under the gate insulation film.

In recent years, many processes have been developed to produce high-performance MOSFETs by increasing mobility of electrons or holes. One of the methods for increasing electron or hole mobility is to change the energy band structure of the channel area by applying mechanical stress to the channel area. For example, NMOS transistors have improved performance when tensile stress is applied to the channel, and PMOS transistors have improved performance when compressive stress is applied to the channel.

A structure in which a stress film is formed on a transistor to apply stress to the channel area has been proposed. FIG. 1 contains a schematic cross-sectional diagram which illustrates a conventional semiconductor device, specifically a transistor, having a stress film formed on the device.

Referring to FIG. 1, the conventional transistor includes gate patterns formed on a semiconductor substrate 1. The gate patterns include a gate insulation film 11 and a gate electrode 12 stacked on the substrate, a first spacer 13 formed on sidewalls of the gate insulation film 11 and gate electrode 12, a second spacer 14 formed on sidewalls of the first spacer 13, a source/drain area 15 formed in the semiconductor substrate 1 on both sides of the gate patterns, and a silicide layer 16 formed on the semiconductor substrate 1 on both sides of the second spacer 14.

A stress film 18 is conformally formed on the entire surface of the transistor to apply stress to the channel area under the gate structure. However, in the conventional device, when a predetermined level of stress is applied to the channel area, reverse stress (to be referred to as counter-stress, hereinafter) may be applied to the other areas, for example, source/drain areas 15. For example, when the stress film 18 applies tensile stress to the channel area (see \textcircled{1}), compressive stress is applied to both sides of the channel area (see \textcircled{2}). Since the silicide layer 16 is formed on the semiconductor substrate 1 exposed by the gate patterns and the first and second spacers 13 and 14, it is disposed on surfaces of both sides of the channel area. Therefore, the stress applied to the both sides of the channel area affects the silicide layer 16 as well, thereby changing the shape of the silicide layer 16. For example, in a case where the stress film 18 is a tensile stress film, compressive stress is applied to the silicide layer 16, so that it may become distorted inwardly at its side surfaces, as shown in FIG. 2, which contains an image of distortion of the silicide layer in a conventional device. The transformation of the silicide layer 16 prevents the transistor from operating in a stable manner.

### SUMMARY

According to one aspect, the inventive concept is directed to a method of manufacturing a semiconductor integrated circuit device, which includes: forming a gate pattern on a semiconductor substrate, the gate pattern having a gate insulation film and a gate electrode; forming a spacer on sidewalls of the gate pattern; forming a silicide layer on at least one portion of the semiconductor substrate exposed by the gate pattern and the spacer, the silicide layer being formed using a silicide process; forming a stress buffer layer on a resultant structure having the silicide layer; and forming a stress film on the stress buffer layer.

In one embodiment, the stress film is a tensile stress film and the stress buffer layer is a compressive stress film. In one embodiment, the semiconductor integrated circuit device comprises an NMOS transistor.

In one embodiment, the stress film is a compressive stress film and the stress buffer layer is a tensile stress film. In one embodiment, the semiconductor integrated circuit device comprises a PMOS transistor.

In one embodiment, the stress film is one of a tensile stress film and a compressive stress film, and the stress buffer layer is the other of the tensile stress film and the compressive stress film. A ratio of a thickness of the stress buffer layer to a thickness of the stress film is adjusted to be not greater than a predetermined value, and the thickness of the stress buffer layer is smaller than that of the stress film. In one embodiment, the ratio of the thickness of the stress buffer layer to the thickness of the stress film is greater than or equal to 1/40 and less than or equal to ¼.

In one embodiment, the method further comprises, after forming the silicide layer, plasma processing the silicide layer using nitrogen-containing gas.

In one embodiment, the spacer includes a first spacer formed on sidewalls of the gate pattern and a second spacer disposed on sidewalls of the first spacer. The method further comprises, after forming the silicide layer, reducing a thickness and a height of the second spacer by partially removing the second spacer.

In one embodiment, the spacer includes a first spacer disposed on sidewalls of the gate pattern and a second spacer disposed on sidewalls of the first spacer. The method further comprises, after forming the silicide layer, reducing a thickness and a height of the second spacer by partially removing the second spacer.

According to another aspect, the inventive concept is directed to a method of manufacturing a semiconductor integrated circuit device, which includes: forming a gate pattern on the semiconductor substrate, the gate pattern having a gate insulation film and a gate electrode; forming a first spacer on sidewalls of the gate pattern and a second spacer on sidewalls of the first spacer; forming a silicide layer on at least one portion of the semiconductor substrate exposed by the gate pattern, the first spacer and the second spacer, the silicide layer being formed using a silicide process; reducing a thickness and a height of the second spacer by partially removing the second spacer; and forming a stress film on a resultant structure having the partially removed second spacer.

In one embodiment, partially removing of the second spacer is performed by at least one of dry etching and wet etching.

In one embodiment, the method further comprises, after forming the silicide layer, plasma processing the silicide layer using nitrogen-containing gas.

In one embodiment, the semiconductor integrated circuit device comprises an NMOS transistor, and the stress film is a tensile stress film.

In one embodiment, the semiconductor integrated circuit device comprises a PMOS transistor, and the stress film is a compressive stress film.

According to another aspect, the inventive concept is directed to a method of manufacturing a semiconductor integrated circuit device, which includes: forming a gate pattern on a semiconductor substrate, the gate pattern having a gate insulation film and a gate electrode; forming a first spacer on sidewalls of the gate pattern; forming a second spacer on sidewalls of the first spacer; forming a silicide layer on at least one portion of the semiconductor substrate exposed by the gate pattern and the first and second spacers, the silicide layer being formed using a silicide process; plasma processing the silicide layer using nitrogen-containing gas; reducing a thickness and a height of the second spacer by partially removing the second spacer; forming a stress buffer layer on a resultant structure having the plasma-processed silicide layer and the partially removed second spacer; and forming a stress film on the stress buffer layer.

In one embodiment, the stress film is one of a tensile stress film and a compressive stress film; and the stress buffer layer is the other of the tensile stress film and the compressive stress film.

In one embodiment, the semiconductor integrated circuit device comprises an NMOS transistor, and the stress film is a tensile stress film.

In one embodiment, the semiconductor integrated circuit device comprises a PMOS transistor, and the stress film is a compressive stress film.

In one embodiment, the ratio of the thickness of the stress buffer layer to the thickness of the stress film is greater than or equal to 1/40 and less than or equal to ¼.

### BRIEF DESCRIPTION OF THE DRAWINGS

The foregoing and other features and advantages of the inventive concept will be apparent from the more particular description of preferred embodiments of the inventive concept, as illustrated in the accompanying drawings in which like reference characters refer to the same parts throughout the different views. The drawings are not necessarily to scale, emphasis instead being placed upon illustrating the principles of the inventive concept. In the drawings, the thickness of layers and regions are exaggerated for clarity.

FIG. 1 contains a schematic cross-sectional diagram which illustrates a conventional semiconductor device, specifically a transistor, having a stress film formed on the device.

FIG. 2 contains an image illustrating distortion of a silicide layer in a conventional device caused by mechanical stress being applied to the device.

FIGS. 3 through 11 are schematic cross-sectional diagrams sequentially illustrating a process of manufacturing a semiconductor integrated circuit device according to embodiments of the present inventive concept.

FIGS. 12A and 12B are diagrams for comparing a stress film in the presence of a pinch-off phenomenon and a stress film in the absence of a pinch-off phenomenon, in which stress is applied to predetermined areas in a structure having a tensile stress film formed on a NMOS transistor, in this exemplary illustration. In FIGS. 12A and 12B, darker regions indicate larger stress applied to the regions.

FIG. 13 is a partially enlarged view of a plasma-processed silicide layer, according to embodiments of the inventive concept.

FIG. 14 is a plan view image of a semiconductor integrated circuit device according to an embodiment of the present inventive concept.

FIG. 15 is a diagram for comparing the operation characteristics of a transistor with a stress buffer layer and a transistor without a stress buffer layer.

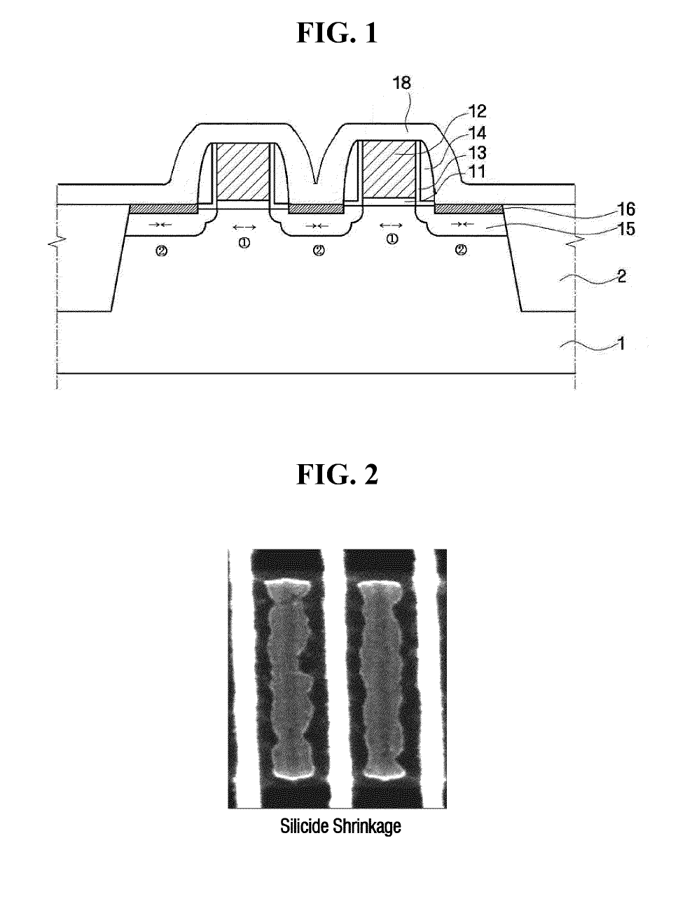

### DETAILED DESCRIPTION OF THE EMBODIMENTS

Advantages and features of the present inventive concept and methods of accomplishing the same may be understood more readily by reference to the following detailed description of preferred embodiments and the accompanying drawings. The present inventive concept may, however, be embodied in many different forms and should not be construed as being limited to the embodiments set forth herein. Rather, these embodiments are provided so that this description will be thorough and complete and will fully convey the inventive concept to those skilled in the art, and the present inventive concept will only be defined by the appended claims.

It will be understood that when an element or layer is referred to as being “on,” or “connected to” another element or layer, it can be directly on or connected to the other element or layer, or intervening elements or layers may be present. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

Spatially relative terms, such as “below,” “beneath,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

Exemplary embodiments of the present inventive concept are described herein with reference to cross-section illustrations that are schematic illustrations of idealized embodiments (and intermediate structures) of the present inventive concept. As such, variations from the shapes of the illustrations as a result, for example, of manufacturing techniques and/or tolerances, are to be expected. Thus, exemplary embodiments of the present inventive concept should not be construed as limited to the particular shapes of areas illustrated herein but are to include deviations in shapes that result, for example, from manufacturing.

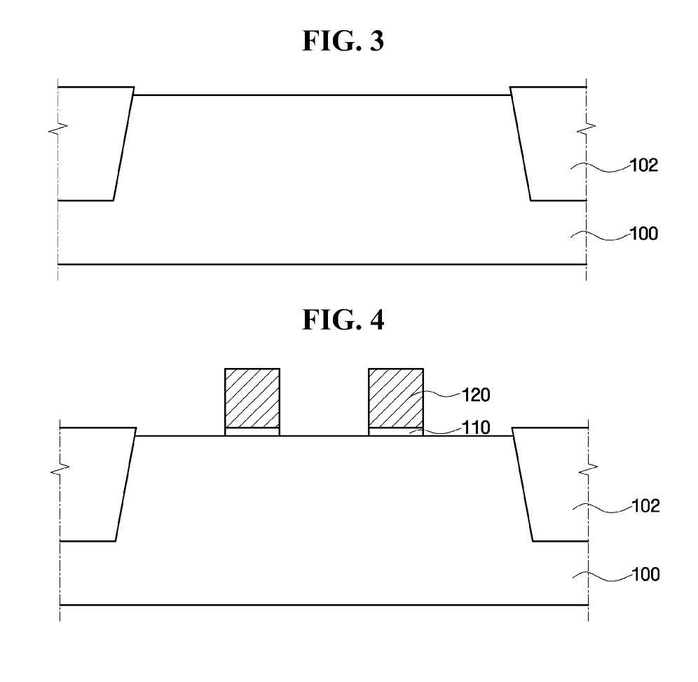

A semiconductor integrated circuit device and a manufacturing process of a semiconductor integrated circuit device according to an embodiment of the present inventive concept will now be described in detail with reference to FIGS. 3 through 11. FIGS. 3 through 11 are schematic cross-sectional diagrams sequentially illustrating a manufacturing process of a semiconductor integrated circuit device according to embodiments of the present inventive concept.

Referring first to FIG. 3, an isolation area 102 is formed in the semiconductor substrate 100. The isolation area 102 defines an active area and an inactive area of the semiconductor substrate 100. The semiconductor substrate 100 may be, for example, a silicon substrate, an SOI (Silicon On Insulator) substrate, a GaAs substrate, a SiGe substrate, a Ce substrate, a quartz substrate, or a glass substrate for a display. The semiconductor substrate 100 may be a P-type or N-type substrate. Although not shown, the semiconductor substrate 100 may include a P-type well or an N-type well doped with p- or n-type impurities. The isolation area 102 that defines the active area and the inactive area may be formed using a process such as STI (Shallow Trench Isolation) or FOX (Field OXide).

Referring to FIG. 4, a stacked structure including a gate insulation film 110 and a gate electrode 120 is formed on the semiconductor substrate 100. Specifically, an insulation film for the gate insulation film and a conductive film for the gate electrode are sequentially deposited on the semiconductor substrate 100 and are subsequently patterned, thereby forming the gate insulation film 110 and the gate electrode 120. The gate insulation film 110 may be made of a material, such as silicon oxide (SiOx), silicon oxynitride (SiON), titanium oxide (TiOx) or tantalum oxide (TaOx). The gate insulation film 110 may be formed by a process such as chemical vapor deposition (CVD) or sputtering. The gate electrode 120 is a conductor and may have a stacked structure of one or more of a polysilicon film which is doped with n- or p-type impurity, a metal film, a metal silicide film or a metal nitride film. Examples of the metal included in the gate electrode 120 may include tungsten (W), cobalt (Co), nickel (Ni), titanium (Ti), tantalum (Ta) and/or other such metals. In the following description, the stacked structure of the gate insulation film 110 and the gate electrode 120 is referred to as gate patterns 110 and 120.

As described above in detail, in one exemplary embodiment, the gate patterns 110 and 120 have a stacked structure of the gate insulation film 110 and the gate electrode 120. However, in alternative embodiments, a gate hard mask (not shown) made of an insulation film may further be formed on the gate electrode 120. That is to say, in alternative embodiments, the gate pattern may have a stacked structure of the gate insulation film 110, the gate electrode 120 and the gate hard mask (not shown).

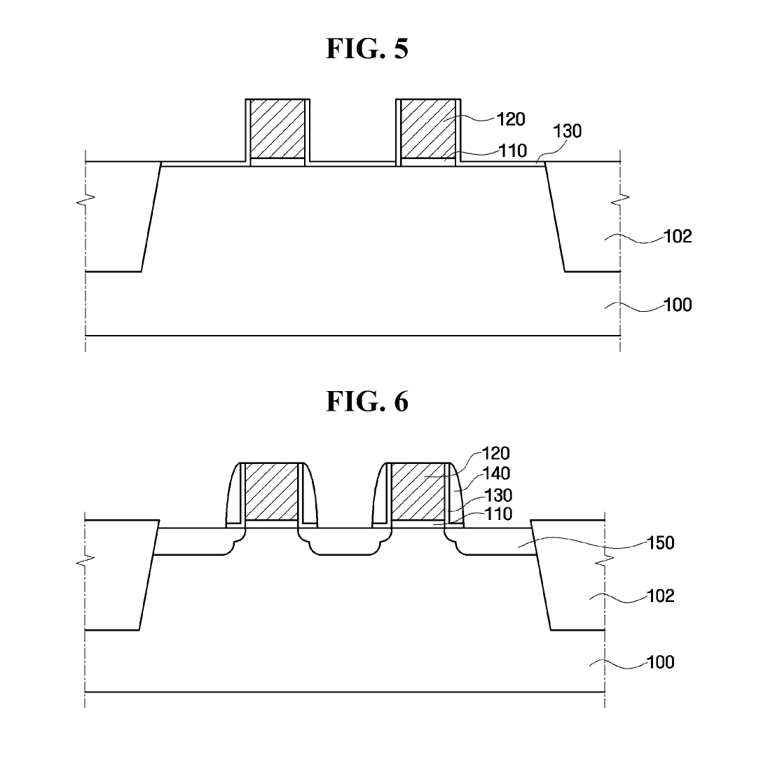

Referring to FIG. 5, the first spacer 130 is formed on sidewalls of the gate patterns 110 and 120. The first spacer 130 may be formed by, for example, performing an oxidation process. When the oxidation process is performed, an oxide film is formed while it extends from the sidewalls of the gate patterns 110 and 120 to the active area of the semiconductor substrate 100. In one embodiment, this oxide film formed on the sidewalls of the gate patterns 110 and 120 corresponds to the first spacer 130, which protects side surfaces of the gate electrode 120. In addition, while the oxidation process is performed for the purpose of forming the first spacer 130, defects of the semiconductor substrate 100 may be remedied, thereby improving the reliability of the semiconductor device being formed.

Referring to FIG. 6, the second spacer 140 is formed on sidewalls of the first spacer 130, and the source/drain area 150 is formed in the semiconductor substrate 100 at opposite sides of the gate patterns 110 and 120, as shown. In one particular exemplary embodiment, the source/drain area 150 may have a lightly doped drain (LDD) structure.

In one particular exemplary embodiment, low-concentration impurities for forming the source/drain area 150 having a LDD structure are ion-implanted into the semiconductor substrate 100 exposed by the gate patterns 110 and 120, using the gate patterns 110 and 120 as masks.

An insulation film (not shown) is conformally formed on the entire surface of the resultant structure having the gate patterns 110 and 120 and the first spacer 130. In one particular exemplary embodiment, the insulation film may be, for example, a nitride film and may be formed by, for example, CVD. The insulation film is anisotropically etched to form the second spacer 140 on the sidewalls of the first spacer 130.

High-concentration impurities are ion-implanted into the semiconductor substrate 100 exposed by the second spacer 140, using the second spacer 140 as a mask, thereby completing the source/drain area 150.

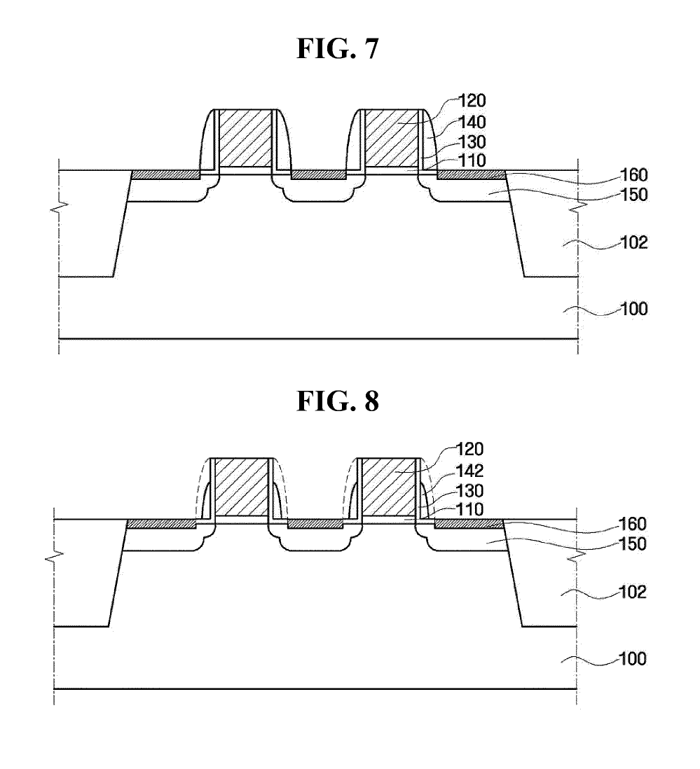

Referring to FIG. 7, the silicide layer 160 is formed on the semiconductor substrate 100 exposed by the second spacer 140 by performing a silicide process. In order to form the silicide layer 160, a metal layer (not shown) is formed on the structure, and an annealing process is then performed under predetermined processing conditions. As a result, a silicide reaction is induced at an interface area where the metal layer and silicon contact each other, thereby forming the silicide layer 160 on the portions of the semiconductor substrate 100 exposed by the second spacer 140. Any unreacted portions of the metal layer are removed by an etching or cleaning process.

In the illustrated exemplary embodiment, the silicide layer 160 is formed on the semiconductor substrate 100. However, in an alternative embodiment, the gate electrode 120 includes silicon and a top portion of the gate electrode 120 is not covered by, for example, a gate hard mask (not shown), but is exposed. In this alternative embodiment, a silicide layer (not shown) may further be formed on the gate electrode 120 as well as on the semiconductor substrate 100.

Referring to FIG. 8, at least a portion of the second spacer 140 is at least partially removed to reduce a height and a thickness of the second spacer 140, as illustrated in FIG. 8 by dashed lines. The partially removed second spacer 140 will be referred to herein as a second spacer pattern 142. The forming of the second spacer pattern 142 may be performed by dry or wet etching. As previously described, when the second spacer 140 is formed of a nitride film, the second spacer pattern 142 may be formed using a nitride film etching gas or a nitride film etching solution, such as phosphoric acid.

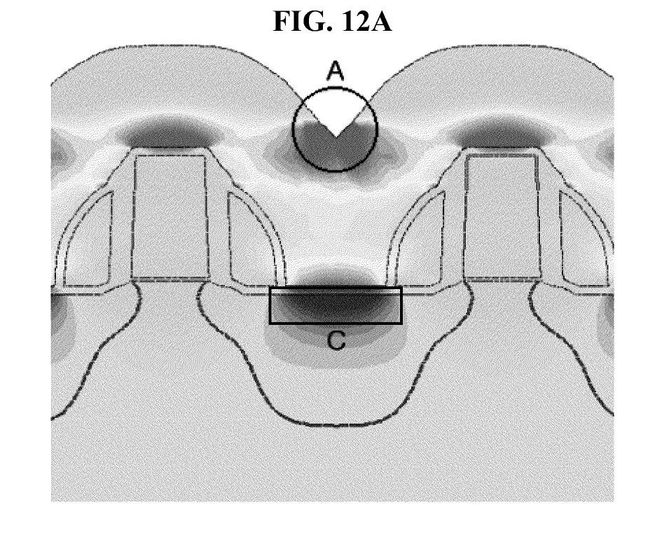

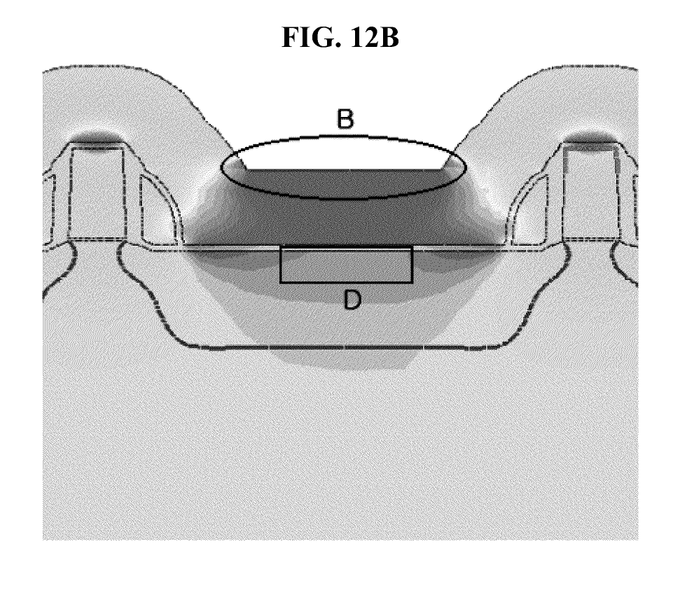

This process is performed to prevent a pinch-off phenomenon from occurring in a subsequent stress film forming process. The pinch-off phenomenon causes transformation of the silicide layer 160, which will be described in more detail below with reference to FIGS. 12A and 12B.

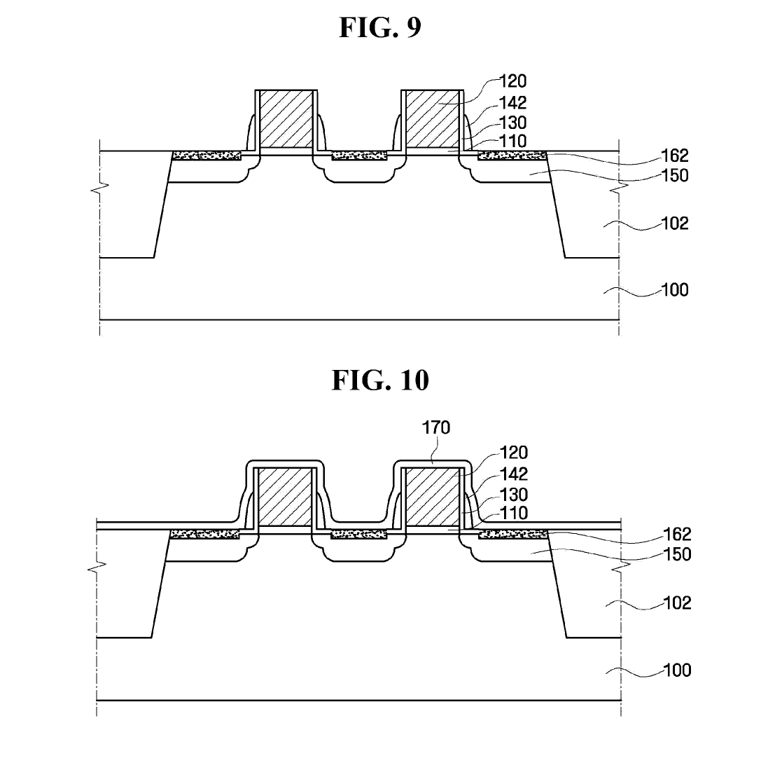

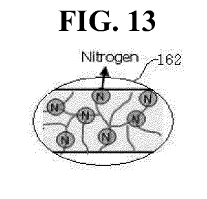

Referring to FIG. 9, the silicide layer 160 is subjected to a plasma process using a nitrogen-containing gas, thereby forming the plasma-processed silicide layer 162. The plasma-processed silicide layer 162 includes a larger amount of nitrogen elements compared to the silicide layer 160 of the previous process. The nitrogen-containing gas used in the plasma process may include N₂ gas or N₂O gas. This process is performed to prevent the silicide layer 162 from being transformed by a stress film formed in a subsequent process, which will be described below in greater detail with reference to FIG. 13.

The transistor shown in FIG. 9 is formed through the process described with reference to FIGS. 3 through 9.

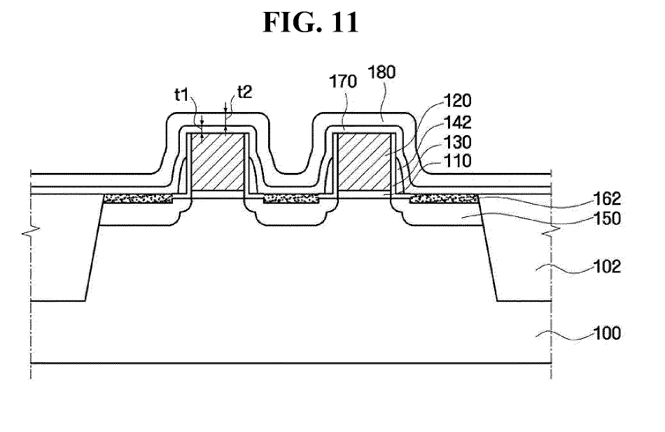

Referring to FIGS. 10 and 11, a stress buffer layer 170 is formed on the entire surface of the structure shown in FIG. 9, that is, in this exemplary embodiment, the transistor. A stress film 180 is then formed on the stress buffer layer 170. The stress buffer layer 170 may be substantially conformally formed on the entire surface of the structure shown in FIG. 9, and the stress film 180 may be substantially conformally formed on the stress buffer layer 170.

In accordance with exemplary embodiments of the inventive concept, the stress buffer layer 170 may be formed of a film capable of applying counter-stress, that is, stress applied in a direction opposite to that of the stress applied from the stress film 180. For example, when the stress film 180 is a tensile stress film that can apply tensile stress to the channel area of a transistor, the stress buffer layer 170 may be a compressive stress film. Alternatively, when the stress film 180 is a compressive stress film that can apply compressive stress to the channel area of a transistor, the stress buffer layer 170 may be a tensile stress film.

In a case where the stress film 180 is a tensile stress film and the stress buffer layer 170 is a compressive stress film, the stress film 180 may be formed of for example, a nitride film made of, for example, SiN, and may be formed using low pressure chemical vapor deposition (LPCVD) in this case, the stress buffer layer 170 may be formed of, for example, a nitride film made of for example, SiN, or an oxide film made of for example, SiO₂, and may be formed using plasma enhanced chemical vapor deposition (PECVD). The present inventive concept is not limited to this illustrated exemplary embodiment. The tensile stress film and the compressive stress film can be separately formed by appropriately adjusting deposition conditions of pressure, temperature, or the like.

In contrast, in a case where the stress film 180 is a compressive stress film and the stress buffer layer 170 is a tensile stress film, the stress film 180 may be formed of, for example, a nitride film made of, for example, SiN, and may be formed using plasma enhanced chemical vapor deposition (PECVD). The stress buffer layer 170 may be formed of for example, a nitride film made of, for example, SiN, or an oxide film made of, for example, SiO₂, and may be formed using low pressure chemical vapor deposition (LPCVD). The present inventive concept is not limited to the illustrated embodiment, but the tensile stress film and the compressive stress film can be separately formed by appropriately adjusting deposition conditions of pressure, temperature, or the like.

In a case where the transistor of this embodiment is an N-type transistor, the stress buffer layer 170 may be a compressive stress film and the stress film 180 may be a tensile stress film. In contrast, in a case where the transistor of this embodiment is a P-type transistor, the stress buffer layer 170 may be a tensile stress film, and the stress film 180 may be a compressive stress film.

According to the inventive concept, the stress buffer layer 170 can suppress the stress applied to both sides of the channel area by forming the stress buffer layer 170 and the stress film 180 in the above-described manner, thereby preventing the silicide layer 162 from being transformed, that is, distorted. For example, in a case where the stress film 180 is a tensile stress film, the stress buffer layer 170 may be a compressive stress film, which can suppress the compressive stress applied to both sides of the channel area. In a case where the stress film 180 is a compressive stress film, the stress buffer layer 170 may be a tensile stress film, which can suppress the tensile stress applied to both sides of the channel area.

It is noted that the formation of the stress buffer layer 170 may defeat the effect of forming the stress film 180, that is, the mobility of electrons or holes may increase so that the operational performance of a transistor may be improved. However, this may be overcome by adjusting a ratio of a thickness t1 of the stress buffer layer 170 to a thickness t2 of the stress film 180 to be a predetermined ratio or less.

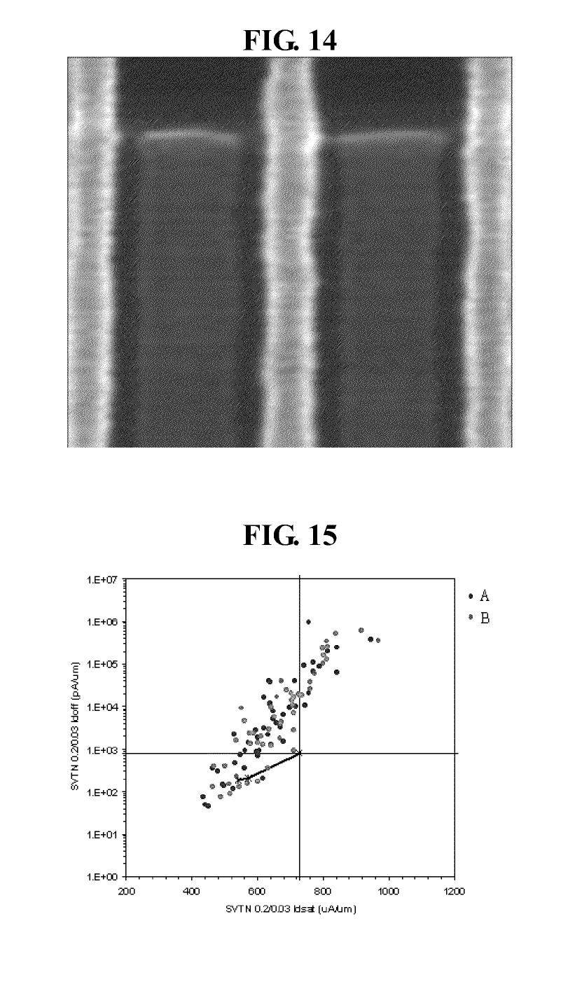

As described above, the ratio of the thickness t1 of the stress buffer layer 170 to the thickness t2 of the stress film 180 is adjusted to be a predetermined ratio or less, thereby applying counter-stress to both sides of the channel area so as to prevent the silicide layer 162 from being transformed or distorted, while maintaining the same effect of forming the stress film 180. In one embodiment, the ratio of the thickness t1 of the stress buffer layer 170 relative to the thickness t2 of the stress film 180, that is, t1/t2, may be in a range of 1/40 to ¼. For example, when the thickness t2 of the stress film 180 is 400 Å, the thickness t1 of the stress buffer layer 170 may be in a range of 10 to 100 Å. If the ratio of the thickness t1 of the stress buffer layer 170 to the thickness t2 of the stress film 180, that is, t1/t2, is excessively small, that is, less than 1/40, the stress buffer layer 170 may not function properly. Conversely, if the ratio of the thickness t1 of the stress buffer layer 170 to the thickness t2 of the stress film 180 is excessively large, that is, greater than ¼, the effect of forming the stress film 180 may be degraded. Therefore, the ratio of the thickness t1 of the stress buffer layer 170 to the thickness t2 of the stress film 180 is adjusted appropriately, which will be described below in more detail with reference to experimental examples shown in FIGS. 14 and 15.

As described above, in the exemplary embodiments of the present inventive concept, the shape of the silicide layer 160 is prevented from being transformed or distorted by performing the partial removal of the second spacer 140 (see FIG. 8), the plasma processing of the silicide layer 160 using a nitrogen-containing gas (see FIG. 9) and the forming of the stress buffer layer 170 (see FIG. 10). However, the present inventive concept is not limited to the illustrated exemplary embodiments, but only one or a combination of two of the above-referenced processes may be performed in order to prevent the shape of the silicide layer 160 from being transformed or distorted.

In the following description, the specific effects of the partial removal of the second spacer 140 (see FIG. 8), will be described in further detail with reference to FIGS. 12A and 12B, and the specific effects of the plasma processing of the silicide layer 160 (see FIG. 9) will be described in detail with reference to FIG. 13.

FIGS. 12A and 12B are diagrams for comparing a stress film in the presence of a pinch-off phenomenon and a stress film in the absence of a pinch-off phenomenon, in which stress is applied to predetermined areas in a structure having a tensile stress film formed on a NMOS transistor, in this exemplary illustration.

FIG. 12A illustrates that a pinch-off phenomenon occurs to a stress film with a vertically overlapping portion disposed between neighboring gates which are relatively close to each other. The pinch-off phenomenon is shown to have a sharp profile (see the circled portion of FIG. 12A labeled ‘A’). In contrast, FIG. 12B illustrates a pinch-off phenomenon does not occur to a stress film without an overlapping portion disposed between neighboring gates which are spaced relatively far apart. Instead of the sharp profile, the device of FIG. 12B is shown to have a planar profile (see a ‘B’ portion).

Referring to FIGS. 12A and 12B, when the pinch-off phenomenon occurs to a stress film, compressive stress (see a ‘C’ portion of FIG. 12A) applied to both sides of a channel area of the stress film is much larger than compressive stress (see a ‘D’ portion of FIG. 12B) applied to both sides of a channel area of the stress film.

Therefore, as in the process shown in FIG. 8, the effect of increasing a distance between the gates can be obtained by partially removing the second spacer 140 to reduce the height and thickness of the second spacer 140, thereby preventing occurrence of the pinch-off phenomenon. Accordingly, the stress applied to both sides of the channel area can be reduced, thereby reducing deformation of the silicide layer 160.

Completely removing the second spacer 140, rather than partially removing the second spacer 140, may cause the stress film disposed between neighboring gates to be incompletely filled, resulting in creation of voids in the stress film, thereby degrading stress film characteristics. Therefore, as shown in FIG. 8, the second spacer 140 is partially removed while some of the second spacer 140 remains.

FIG. 13 is a partially enlarged view of a plasma-processed silicide layer, according to exemplary embodiments of the inventive concept. As in the process shown in FIG. 9, the silicide layer 160 is plasma-processed using nitrogen-containing gas, so that the plasma-processed silicide layer 162 contains a large amount of nitrogen elements.

In this exemplary embodiment, as shown in FIG. 13, the nitrogen elements contained in the plasma processed silicide layer 162 are disposed in the silicide grain boundary of the silicide layer 162. If the nitrogen elements are disposed in the silicide grain boundary, the surface energy of the silicide grain boundary decreases, so that deformation of the silicide layer 162 can be suppressed even with the stress applied to the silicide layer 162.

Hereinafter, an exemplary experimental example of the present inventive concept will be described with reference to FIGS. 14 and 15, in which a transistor is formed by a manufacturing process according to an embodiment of the present inventive concept, and a stress film is disposed on the transistor.

FIG. 14 is a plan view image of a semiconductor integrated circuit device according to an embodiment of the present inventive concept. In this specific exemplary embodiment, the semiconductor integrated circuit device shown in FIG. 14 has a tensile stress film disposed on an NMOS transistor. The illustrated semiconductor integrated circuit device is manufactured according to various embodiments of the inventive concept such that in the oxide and nitride film spacers formed on sidewalls of the gate, the nitride film spacer is partially removed, a silicide layer disposed on both sides of the nitride film spacer are plasma processed using nitrogen-containing gas, a compressive stress film formed of an oxide film as a stress buffer layer is formed to a thickness of 50 Å, and a tensile stress film formed of a nitride film as a stress film is formed to a thickness of 400 Å.

As confirmed from FIG. 14, the silicide layer demonstrates little deformation even with the existence of the tensile stress film.

FIG. 15 is a diagram comparing the operation characteristics of transistors with and without a stress buffer layer according to the inventive concept. FIG. 15 shows the operation characteristics of a transistor of the semiconductor integrated circuit device shown in FIG. 14 (data points labeled ‘A’) and a transistor of a semiconductor integrated circuit device substantially the same as the semiconductor integrated circuit device shown in FIG. 14, except that no stress buffer layer is provided (see data points labeled ‘B’). Specifically, FIG. 15 shows transistor characteristics of drain saturation current (Idsat) relative to drain off current (Ioff).

Referring to FIG. 15, in cases where a stress buffer layer is provided (see data points labeled ‘A’) and a stress buffer layer is not provided (see data points labeled ‘B’), there is little difference in the transistor characteristics of drain saturation current (Idsat) relative to drain off current (Ioff). That is, in a case where a tensile stress film made of a nitride film is formed as a stress film to a thickness of 400 Å, even if a compressive stress film made of an oxide film is formed as a stress buffer layer to a thickness of 50 Å, compared to a case where a stress buffer layer is not provided, the transistor characteristics are not affected. This is because the thickness of the stress buffer layer is adjusted to be smaller than that of the stress film, as described above in detail.

Since the stress buffer layer is formed in the above-described manner, deformation of the silicide layer can be prevented without degrading the stress film formation effect.

While the present inventive concept has been particularly shown and described with reference to exemplary embodiments thereof, it will be understood by those of ordinary skill in the art that various changes in form and details may be made herein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the inventive concept.

What is claimed is:

1. A method of manufacturing a semiconductor integrated circuit device, comprising:
forming a gate pattern on a semiconductor substrate, the gate pattern having a gate insulation film and a gate electrode;
forming a spacer on sidewalls of the gate pattern;
forming a silicide layer on at least one portion of the semiconductor substrate exposed by the gate pattern and the spacer, the silicide layer being formed using a silicide process;
forming a stress buffer layer on a resultant structure having the silicide layer; and
forming a stress film on the stress buffer layer.

2. The method of claim 1, wherein the stress film is a tensile stress film and the stress buffer layer is a compressive stress film.

3. The method of claim 2, wherein the semiconductor integrated circuit device comprises an NMOS transistor.

4. The method of claim 1, wherein the stress film is a compressive stress film and the stress buffer layer is a tensile stress film.

5. The method of claim 4, wherein the semiconductor integrated circuit device comprises a PMOS transistor.

6. The method of claim 1, wherein:
the stress film is one of a tensile stress film and a compressive stress film, and the stress buffer layer is the other of the tensile stress film and the compressive stress film; and
a ratio of a thickness of the stress buffer layer to a thickness of the stress film is adjusted to be not greater than a predetermined value, and the thickness of the stress buffer layer is smaller than that of the stress film.

7. The method of claim 6, wherein the ratio of the thickness of the stress buffer layer to the thickness of the stress film is greater than or equal to 1/40 and less than or equal to ¼.

8. The method of claim 1, further comprising, after forming the silicide layer, plasma processing the silicide layer using nitrogen-containing gas.

9. The method of claim 8, wherein:
the spacer includes a first spacer formed on sidewalls of the gate pattern and a second spacer disposed on sidewalls of the first spacer; and
the method further comprises, after forming the silicide layer, reducing a thickness and a height of the second spacer by partially removing the second spacer.

10. The method of claim 1, wherein:
the spacer includes a first spacer disposed on sidewalls of the gate pattern and a second spacer disposed on sidewalls of the first spacer; and
the method further comprises, after forming the silicide layer, reducing a thickness and a height of the second spacer by partially removing the second spacer.

11. A method of manufacturing a semiconductor integrated circuit device comprising:
forming a gate pattern on the semiconductor substrate, the gate pattern having a gate insulation film and a gate electrode;
forming a first spacer on sidewalls of the gate pattern and a second spacer on sidewalls of the first spacer;
forming a silicide layer on at least one portion of the semiconductor substrate exposed by the gate pattern, the first spacer and the second spacer, the silicide layer being formed using a silicide process;
reducing a thickness and a height of the second spacer by partially removing the second spacer; and
forming a stress film on a resultant structure having the partially removed second spacer.

12. The method of claim 11, wherein partially removing of the second spacer is performed by at least one of dry etching and wet etching.

13. The method of claim 11, further comprising, after forming the silicide layer, plasma processing the silicide layer using nitrogen-containing gas.

14. The method of claim 11, wherein the semiconductor integrated circuit device comprises an NMOS transistor, and the stress film is a tensile stress film.

15. The method of claim 11, wherein the semiconductor integrated circuit device comprises a PMOS transistor, and the stress film is a compressive stress film.

16. A method of manufacturing a semiconductor integrated circuit device, comprising:
forming a gate pattern on a semiconductor substrate, the gate pattern having a gate insulation film and a gate electrode;
forming a first spacer on sidewalls of the gate pattern;
forming a second spacer on sidewalls of the first spacer;
forming a silicide layer on at least one portion of the semiconductor substrate exposed by the gate pattern and the first and second spacers, the silicide layer being formed using a silicide process;
plasma processing the silicide layer using nitrogen-containing gas; and
forming a stress film on a resultant structure having the plasma-processed silicide layer.

17. The method of claim 16, further comprising, after plasma processing the silicide layer, before forming a stress film,
reducing a thickness and a height of the second spacer by partially removing the second spacer;
forming a stress buffer layer on a resultant structure having the plasma-processed silicide layer and the partially removed second spacer; and
wherein:
the stress buffer layer is disposed between the resultant structure having the plasma-processed silicide layer and the partially removed second spacer, and the stress film, and
the stress film is one of a tensile stress film and a compressive stress film; and
the stress buffer layer is the other of the tensile stress film and the compressive stress film.

18. The method of claim 16, wherein:
the semiconductor integrated circuit device comprises an NMOS transistor; and
the stress film is a tensile stress film.

19. The method of claim 16, wherein:
the semiconductor integrated circuit device comprises a PMOS transistor; and
the stress film is a compressive stress film.

20. The method of claim 17, wherein the ratio of the thickness of the stress buffer layer to the thickness of the stress film is greater than or equal to 1/40 and less than or equal to ¼.
